(19) United States
(12) Patent Application Publication
(10) Pub. No.: US 2010/0258955 A1
(43) Pub. Date: Oct. 14, 2010

(54) SEMICONDUCTOR DEVICE AND METHOD OF MANUFACTURING THE SAME

(75) Inventors: YUICHI MIYAGAWA, KANAGAWA (JP); HIDEYUKI HORII, KANAGAWA (JP); KENTA OGAWA, KANAGAWA (JP)

Correspondence Address: YOUNG & THOMPSON, 209 Madison Street, Suite 500, Alexandria, VA, 22314, US

(73) Assignee: NEC ELECTRONICS CORPORATION, KANAGAWA (JP)

(21) Appl. No.: 12/757,177

(22) Filed: Apr. 9, 2010

(30) Foreign Application Priority Data
Apr. 14, 2009 (JP) 2009-098473

(51) Int. Cl. H01L 23/49; H01L 21/60

(52) U.S. Cl. 257/784; 438/121; 257/E21.509; 257/E23.025

(57) ABSTRACT

The semiconductor device includes a substrate over one surface of which an electroless plating electrode film is formed; a semiconductor chip mounted over the one surface of the substrate; and a bonding wire which connects the semiconductor chip and one surface of the electroless plating electrode film, a recessed depth which is a difference between a lowermost height of a bonding portion of the one surface of the electroless plating electrode film to the bonding wire, and an uppermost height of the one surface other than the bonding portion being equal to or less than 1.5 μm.

The application is based on Japanese patent application No. 2009-098473, the content of which is incorporated hereinto by reference.

### BACKGROUND

1. Technical Field

The present invention relates to a semiconductor device and a method of manufacturing the same.

2. Related Art

A metal film termed a stitch for connecting with an electrode (pad) of a semiconductor chip through a bonding wire is formed on a substrate such as a multilayered interconnect substrate on which the semiconductor chip is mounted. In the past, an electrolytic plating electrode film formed by an electrolytic plating method has been used as a stitch. However, the number of pads increases due to high integration of the semiconductor chip, and the density of interconnects drawn from the stitch rises, therefore it has been difficult to perform arrangement of plating interconnects for forming the metal film by the electrolytic plating method. For this reason, henceforth, it is desirable that the metal film is formed by an electroless plating method, which requires no such plating interconnects.

However, there has been a problem that an electroless plating electrode film formed by the electroless plating method is hard compared to the electrolytic plating electrode film, and that good connection is not obtained in performing wire bonding under the same condition as that of the previous electrolytic plating electrode film.

Japanese Unexamined patent publication No. 2001-298038 discloses an example in which wire bonding for connecting a bonding pad portion (stitch) of a conductor pattern of an electroless gold (Au)/nickel (Ni) plating tape carrier, and an element electrode (pad) of a semiconductor chip through a gold wire is performed through an ultrasonic thermal-compression type wire bonder, by providing an ultrasonic output of 0.75 watt (W) or more, and under a low load of 15 to 30 gf. Hereby, it is described that good gold wire bonding properties on the electroless plating tape carrier is guaranteed.

Japanese Unexamined patent publication No. 2000-208548 discloses that in a semiconductor device composed of an external electrode (stitch) and a semiconductor element formed on a (insulating) substrate, and an Au wire for connecting between the external electrode and (a pad on) the semiconductor element, where the external electrode is composed of a Cu interconnect film formed on the insulating substrate, and a multilayered metal film formed on the interconnect film, the multilayered metal film is composed of an electroless Au plating film formed on an uppermost layer, and an underlying metal film formed between the electroless Au plating film and the Cu interconnect film, and Vickers hardness of the underlying metal film is 100 or less.

Japanese Unexamined patent publication No. 2001-274202 discloses that in a Tape Automated Bonding (TAB) tape for potting or transfer molding Ball Grid Array (BGA) where an interconnect pattern having a land (external connection electrode) is formed in copper foil bonded on an adhesive-coated insulating film, hard copper foil is used as copper foil, which is 3 μm to 25 μm in thickness, and is 180 or more in Vickers hardness (HV: measured load 10 gf) of copper foil.

In Japanese Unexamined patent publication No. 2001-298038, conditions such as load or ultrasonic waves when wire bonding is performed are confined to a predetermined range, whereby good gold wire bonding onto the electroless plating tape carrier may be performed.

However, it has been found by the inventors that a root shape of a bonding portion of the bonding wire to the electroless plating electrode film or a shape of a bonding portion of the electroless plating electrode film to the bonding wire is more important than conditions such as load or ultrasonic waves, in order to obtain a high wire bonding strength when the electroless plating electrode film is used.

### SUMMARY

In one embodiment, there is provided a semiconductor device including:

a substrate over one surface of which an electroless plating electrode film is formed;

a semiconductor chip mounted over the one surface of the substrate; and

a bonding wire which connects the semiconductor chip and one surface of the electroless plating electrode film,

a recessed depth which is a difference between a lowermost height of a bonding portion of the one surface of the electroless plating electrode film to the bonding wire, and an uppermost height of the one surface other than the bonding portion being equal to or less than 1.5 μm.

In another embodiment, there is provided a method of manufacturing a semiconductor device semiconductor device, including,

connecting a semiconductor chip and one surface of an electroless plating electrode film through a bonding wire, the electroless plating electrode film being formed over one surface of a substrate, the semiconductor chip being mounted over the one surface of the substrate, and the connecting the semiconductor chip and the one surface of the electroless plating electrode film through the bonding wire, including leading out a portion of the bonding wire from a tip of a capillary, bringing the capillary into contact with the one surface of the electroless plating electrode film, and connecting the portion of the bonding wire to the one surface of the electroless plating electrode film so that a recessed depth which is a difference between a lowermost height of a bonding portion of the one surface of the electroless plating electrode film to the bonding wire, and an uppermost height of the one surface other than the bonding portion becomes equal to or less than 1.5 μm.

According to this configuration, it is possible to obtain a high wire bonding strength when wire bonding is performed with respect to the electroless plating electrode film. When the bonding wire is connected to the electroless plating electrode film, the capillary is thrust into the electroless plating electrode film using the capillary. For this reason, when the bonding wire is attempted to be connected to a hard electroless plating electrode film, a recess of the electroless plating electrode film becomes large.

However, it has been found by the inventors that when the bonding wire is connected to the electroless plating electrode film, a portion, where less crushing of the root of the bonding portion of the bonding wire to the electroless plating electrode film occurs, has a higher wire bonding strength. In addition, the inventors have found that it is preferable that a recessed depth of the bonding portion of the electroless plating electrode film to the bonding wire is set to be equal to or less than 1.5 μm in order to obtain such a shape of the bonding wire.

In the past, when the electrolytic plating electrode film has been used, it has been considered that the impact of a shape of the bonding portion of the electrolytic plating electrode film to the bonding wire on the wire bonding strength was extremely slight, because the electrolytic plating electrode film itself was flexible. Further, in Japanese Unexamined patent publication Nos. 2001-298038, 2000-208548 and 2001-274202, such a shape of the bonding portion of the electroless plating electrode film to the bonding wire is not considered. In Japanese Unexamined patent publication No. 2001-298038, conditions such as load or ultrasonic waves are mentioned. However, as described later, it is not possible to properly form the shape of the bonding portion of the electroless plating electrode film under such conditions.

In the meantime, any combination of the above-mentioned components, or conversion of the expression of the invention between methods, devices and the like is also effective as an aspect of the invention.

According to the invention, when wire bonding is performed with respect to the electroless plating electrode film, it is possible to obtain a wire bonding strength having high reliability.

### BRIEF DESCRIPTION OF THE DRAWINGS

The above and other objects, advantages and features of the present invention will be more apparent from the following description of certain preferred embodiments taken in conjunction with the accompanying drawings, in which:

FIGS. 1A and 1B are cross-sectional views illustrating a manufacturing procedure of a semiconductor device in an embodiment of the invention;

FIG. 2 is a cross-sectional view illustrating a manufacturing procedure of the semiconductor device in the embodiment of the invention;

FIG. 3 is a cross-sectional view illustrating a manufacturing procedure of the semiconductor device in the embodiment of the invention;

FIGS. 4A and 4B are enlarged sectional views illustrating a procedure when a bonding wire is bonded on an electroless plating electrode film in the embodiment of the invention;

FIG. 5 is an enlarged sectional view illustrating a bonding portion of the electroless plating electrode film and the bonding wire in the embodiment of the invention; and

FIG. 6 is a diagram illustrating a relationship between tensile strength of the electroless plating electrode film and the bonding wire, and the recessed depth of the bonding portion of the electroless plating electrode film to the bonding wire.

### DETAILED DESCRIPTION

The invention will be now described herein with reference to illustrative embodiments. Those skilled in the art will recognize that many alternative embodiments can be accomplished using the teachings of the present invention and that the invention is not limited to the embodiments illustrated for explanatory purposed.

Hereinafter, the embodiment according to the invention will be described with reference to the accompanying drawings. In all the drawings, like elements are referenced by like reference numerals and descriptions thereof will not be repeated.

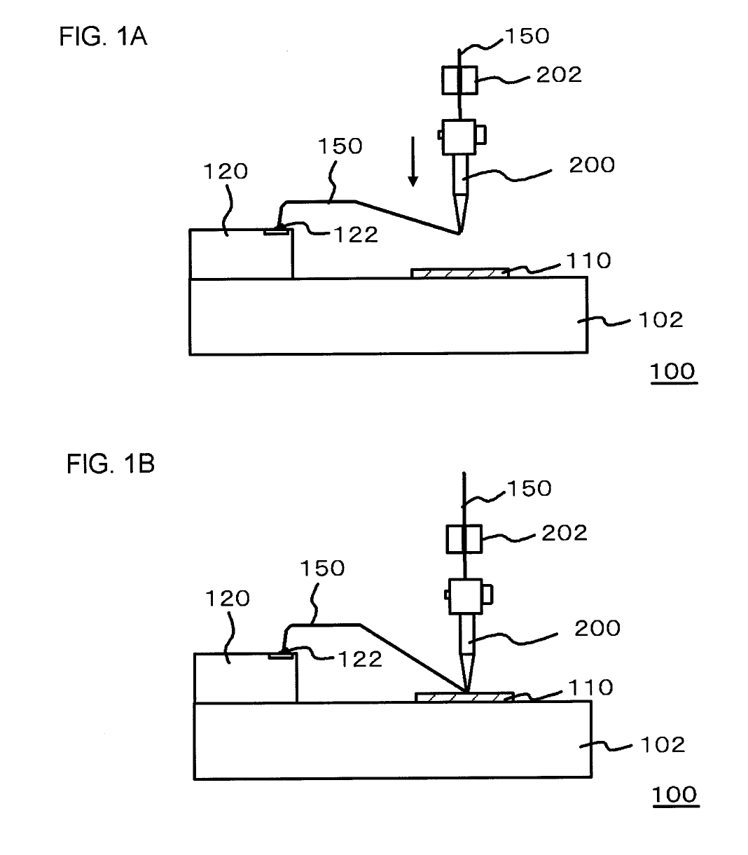

FIGS. 1A and 1B are cross-sectional views illustrating a manufacturing procedure in a semiconductor device of the embodiment.

A semiconductor device 100 includes a substrate 102 on one surface of which an electroless plating electrode film 110 (stitch) is formed, and a semiconductor chip 120 mounted on the one surface of the substrate 102. In the embodiment, the substrate 102 may be a multilayered interconnect substrate in which a plurality of interconnect layers and a plurality of insulating layers are alternatively stacked. Here, the electroless plating electrode film 110 may be formed on at least one side of both surfaces of the substrate 102.

In the embodiment, an electrode pad 122 is formed on one surface of the semiconductor chip 120 opposite to the other surface which is bonded to the substrate 102. Here, there will be described a procedure for connecting the electrode pad 122 and one surface of the electroless plating electrode film 110 opposite to the other surface which is in contact with the substrate 102 by a bonding wire 150. Meanwhile, in the embodiment, a package structure of the semiconductor device 100 is not especially limited, but may be, for example, Ball Grid Array (BGA) or Land Grid Array (LGA) and the like.

The electroless plating electrode film 110 may include an electroless plating metal layer formed on a Cu interconnect layer (not shown) of the surface of the substrate 102, and an electroless plating Au layer formed on the electroless plating metal layer. The electroless plating metal layer may be configured to have equal to or more than 400 of Vickers hardness (HV). In the embodiment, the electroless plating metal layer may include an electroless plating Ni layer. The electroless plating Ni layer may be, for example, formed by immersing the substrate 102 into a catalytic solution including a palladium catalyst, and performing electroless plating of Ni after displacing palladium in a surface of the Cu interconnect layer (not shown) of the surface of the substrate 102. After this, the electroless plating Au layer may be formed by performing electroless plating of Au.

In addition, an electroless plating palladium (Pd) layer may be formed between the electroless plating Ni layer and the electroless plating Au layer. Hereby, it is possible to improve solder connection reliability. In this case, after the electroless plating Ni layer is formed on a surface of the Cu interconnect layer (not shown) of the surface of the substrate 102, the electroless plating Pd layer and the electroless plating Au layer are formed by performing electroless plating of palladium and Au, respectively.

Here, the film thickness of the electroless plating Ni layer may be in the range of, for example, equal to or more than 1.0 μm and equal to or less than 15.0 μm. In addition, the film thickness of the electroless plating Au layer may be in the range of, for example, equal to or more than 0.01 μm and equal to or less than 0.7 μm. In the embodiment, as an example, the electroless plating electrode film 110 may be, for example, configured so that the electroless plating Pd layer (having the film thickness of about 0.03 μm) is formed on the electroless Ni layer (having the film thickness of about 5 μm), and the electroless plating Au layer (having the film thickness of about 0.05 μm) is further formed on the electroless plating Pd layer.

In addition, here, the electroless plating electrode film 110 may include phosphorus (P) or may be amorphous. In this point, the electrode film is different from the electrolytic plating film. For example, the electroless plating Ni layer may include phosphorus (P) or may be amorphous.

Connection of the bonding wire 150 is performed using a capillary 200 and a cut clamp 202. The bonding wire 150 is lead out from a tip of the capillary 200. The cut clamp 202 holds the bonding wire 150 and cuts off the bonding wire 150.

First, one end of the bonding wire 150 is lead out from the tip of the capillary 200 and the one end thereof is connected to the electrode pad 122 (FIG. 1A). Next, another part of the bonding wire 150 of which the one end is connected to the electrode pad 122 is lead out from the tip of the capillary 200, and the another part of the bonding wire 150 is bonded to the electroless plating electrode film 110 by bringing the capillary 200 into contact with one surface of the electroless plating electrode film 110 (FIG. 1B).

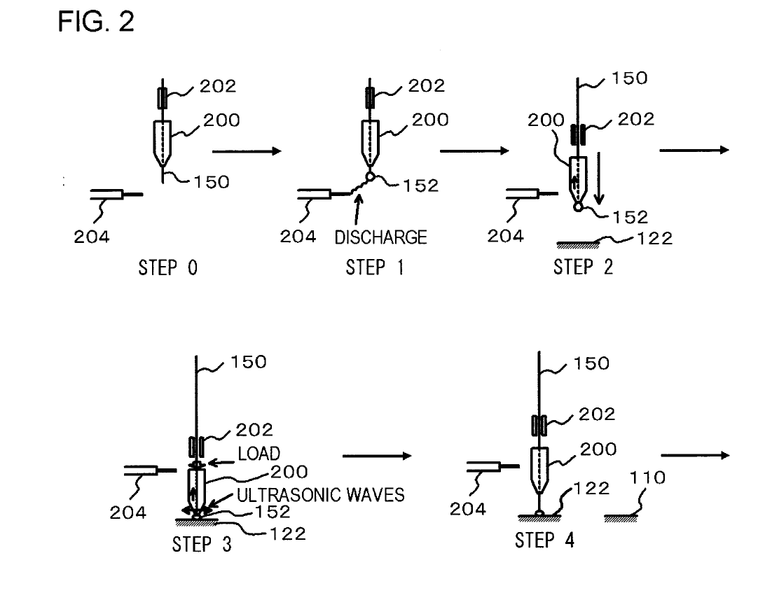

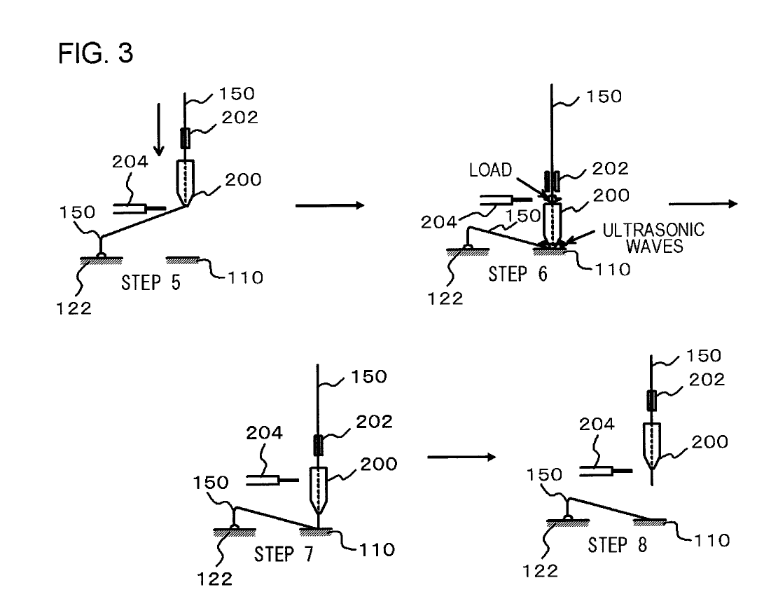

These procedures will be described in detail with reference to FIG. 2 and FIG. 3.

First, at a state (step 0) where one end of the bonding wire 150 (the gold wire) is lead out to the tip of the capillary 200, discharge for ball formation is performed between a spark rod 204 and the bonding wire 150, and then an initial ball 152 is formed on the tip of the bonding wire 150 (step 1). Next, the capillary 200 is let down toward the electrode pad 122 (step 2), and after the initial ball 152 is in contact with the electrode pad 122, the initial ball 152 is bonded to the electrode pad 122 while load and ultrasonic waves of predetermined conditions are applied (step 3). At this time, the substrate 102 (see FIGS. 1A and 1B) is heated at a predetermined temperature. After this, the capillary 200 is pulled up, and the bonding wire 150 is reeled out (step 4).

Next, the capillary 200 is moved to one surface of the electroless plating electrode film 110 (step 5), and the capillary 200 is brought into contact with one surface of the electroless plating electrode film 110 as it is, and then another part of the bonding wire 150 is bonded to the electroless plating electrode film 110 while applying load and ultrasonic waves of predetermined conditions (step 6). After this, the capillary 200 is pulled up, and the bonding wire is reeled out (step 7), and then the bonding wire is ripped off from the electroless plating electrode film 110 while pinching the bonding wire 150 through the cut clamp 202 (step 8). As described above, bonding of one bonding wire 150 is completed, to be in a state of step 0, and afterward, bonding of a predetermined amount of bonding wire 150 is repeated from step 1.

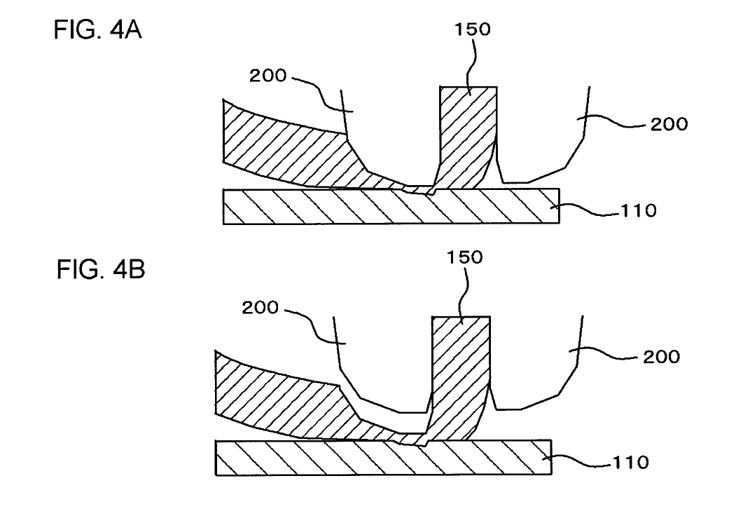

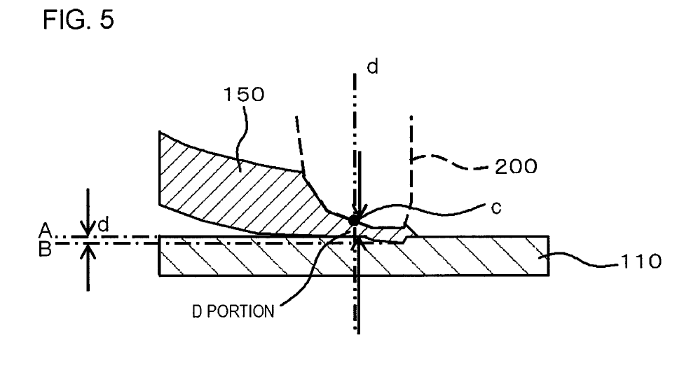

FIGS. 4A and 4B are enlarged sectional views illustrating a procedure when the bonding wire 150 is bonded on the electroless plating electrode film 110. In addition, FIG. 5 is an enlarged sectional view illustrating the bonding portion of the electroless plating electrode film 110 and the bonding wire 150.

The bonding wire 150 led out from the tip of the capillary 200 comes in contact with the electroless plating electrode film 110 in the state of being interposed between the tip of the capillary 200 and the electroless plating electrode film 110 (FIG. 4A). Next, load and ultrasonic waves of predetermined conditions are applied to the capillary 200. After this, the capillary 200 is pulled up (FIG. 4B).

Here, a root shape of the bonding portion of the bonding wire 150 to the electroless plating electrode film 110 or a shape of the bonding portion of the electroless plating electrode film 110 to the bonding wire 150 is determined depending on the heating temperature of the substrate, and the conditions of load and ultrasonic waves applied to the capillary. In the embodiment, in the bonding portion of one surface of the electroless plating electrode film 110 to the bonding wire 150, the bonding wire 150 is bonded to the electroless plating electrode film 110 under the condition that a recessed depth “d” is set to be equal to or less than 1.5 μm, which is a difference between the lowermost depth (line B of FIG. 5) of the bonding portion and the uppermost height (line A of FIG. 5) of the above-mentioned one surface other than the bonding portion. According to this configuration, as described later, wire bonding strength having high reliability is obtained.

Further, in the embodiment, the recessed depth “d” can be set to be equal to or more than 0.05 μm. According to this configuration, an inactive film of a film surface of the electroless plating electrode film 110 is broken, to thereby allow an active film of a lower layer thereof to be exposed, and therefore, electrical connection of the electroless plating electrode film 110 and the bonding wire 150 can be made good, and manufacturing stability can be improved.

In addition, the bonding wire 150 may be formed so that the minimum thickness of a root (mentioned as “D portion” in FIG. 5) which is a bonding portion bonded to the electroless plating electrode film 110 is set to be equal to or more than 2.0 μm. Here, the “D portion” may be set to a distance between a contact c and the electroless plating electrode film 110 along a vertical line d drawn from the contact c to a direction of the substrate 102, where the contact c is a contact between the capillary 200 and the bonding wire 150 when the capillary 200 is brought in contact with the electroless plating electrode film 110. For example, the bonding wire 150 may be set so that the minimum thickness of a root which is a bonding portion bonded to the electroless plating electrode film 110 is equal to or more than 10% of a diameter of another part of the bonding wire 150. According to this configuration, as described later, the wire bonding strength having high reliability is obtained.

### Embodiment

Under the following conditions, wire bonding was implemented so that the recessed depth “d” is set to be almost zero, 0.5 μm, 1.0 μm, 1.5 μm, 2.0 μm, 2.5 μm, and 3.0 μm, by making load and ultrasonic waves different when the bonding wire 150 is connected to the electroless plating electrode film 110 in the procedures described with reference to FIGS. 1A to 4B. The recessed depth “d” was observed through a Scanning Electron Microscope (SEM).

Wire bonding of the bonding wire 150 to the electroless plating electrode film 110 was performed under the following conditions by using Kaijo Corporation-made device name FB-780. The conditions are typical examples.

(a) temperature 150° C., load 20 gf, ultrasonic waves output 50: recessed depth “d”: equal to or more than 0 μm and equal to or less than 1.5 μm

(b) temperature 150° C., load 50 gf, ultrasonic waves output 100: recessed depth “d”: more than 1.5 μm and less than 2.0 μm

(c) temperature 150° C., load 150 gf, ultrasonic waves output 150: recessed depth “d”: equal to or more than 2.0 μm

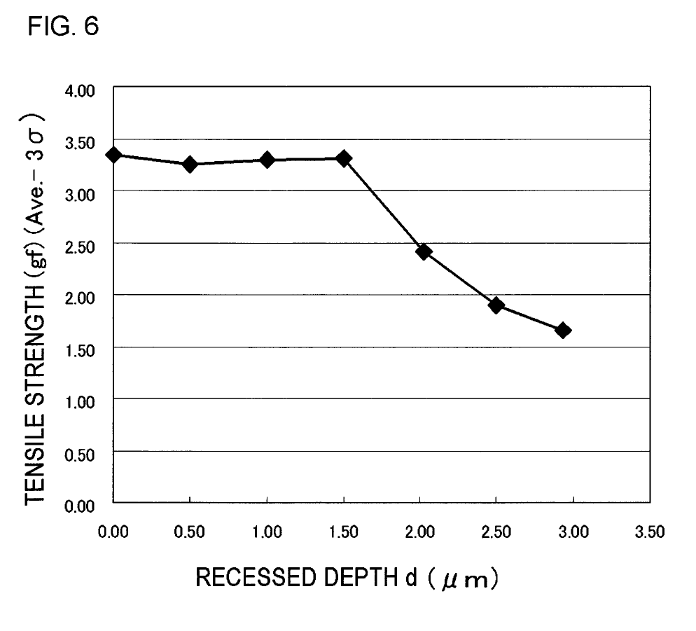

FIG. 6 is a diagram illustrating a relationship between the tensile (PULL) strength of the electroless plating electrode film and the bonding wire, and the recessed depth “d” of the bonding portion of the electroless plating electrode film with the bonding wire. Here, values of the tensile strength (gf) having Ave-3σ are shown in consideration of variation. σ is standard deviation.

The tensile strength was measured in accordance with MIL-STD-883. As shown in FIG. 6, the smaller the recessed depth d of the electroless plating electrode film 110 was, the better the tensile strength could be obtained. Given equal to or more than standard 2.5 gf, the recessed depth d of the electroless plating electrode film 110 may be set to be equal to or less than 1.5 μm. Hereby, it is possible to secure the good bonding properties and the high wire bonding strength.

When the film thickness of the bonding wire 150 of the bonding portion with the electroless plating electrode film 110 was measured through a microscope with a measuring mechanism with respect to a sample of which the recessed depth “d” is equal to or less than 1.5 μm, the minimum thickness thereof was equal to or more than 2 μm. In addition, this value was equal to or more than 10% of a diameter (initial value) of 20 μm of another part of the bonding wire 150. On the other hand, when the film thickness of the bonding wire 150 of the bonding portion with the electroless plating electrode film 110 was measured through the microscope with a measuring mechanism with respect to a sample of which the recessed depth “d” is equal to or more than 2.0 μm, the minimum thickness thereof was thin to less than 2 μm.

From the above descriptions, the wire bonding was perform so that the shape of the bonding portion of the electroless plating electrode film 110 to the bonding wire 150 was in a predetermined range, whereby it was obvious that the root shape of the bonding portion of the bonding wire 150 to the electroless plating electrode film 110 was made good. In addition, hereby, when the wire bonding was performed with respect to the electroless plating electrode film 110, it was obvious that the wire bonding strength having the high reliability was obtained.

Meanwhile, the output value of ultrasonic waves of the device used in the above-mentioned embodiment was converted into watt (W), the value was about 0.5 W when the output of ultrasonic waves was 100, and about 1.10 W when the output of ultrasonic waves was 150. Hereby, as in the condition disclosed in Japanese Unexamined patent publication No. 2001-298038, when the output of ultrasonic waves is large to a degree of 0.75 W, the condition corresponds to the above-mentioned condition (c), and the recessed depth “d” of the electroless plating electrode film is large to equal to or more than 2.0 μm. In this case, the root shape of the bonding portion of the bonding wire to the electroless plating electrode film is not desirably formed, and when the wire bonding is performed with respect to the electroless plating electrode film, it can be understood that the wire bonding strength of the bonding wire having the high reliability is not obtained, and that the range of mass production manufacture becomes narrow.

In addition, although the good tensile strength is obtained even when the recessed depth “d” is zero in measured value, it is preferable that the recessed depth “d” is set to be equal to or more than 0.05 μm, from a point of view that an inactive film of a film surface of the electroless plating electrode film 110 is broken, to thereby cause an active film of a lower layer thereof to be exposed, and therefore, electrical connection of the electroless plating electrode film 110 and the bonding wire 150 is made good, and manufacturing stability is improved.

Next, an effect of the semiconductor device 100 in the embodiment will be described.

Since the bonding wire is pushed by the capillary in the case of connecting the bonding wire to the stitch, the higher the material hardness of the stitch is, the easily the root of the bonding wire is crushed. It has been found by the inventors that when the bonding wire 150 is connected to the electroless plating electrode film 110 having the high hardness, a portion, where less crushing of the root of the bonding portion of the bonding wire 150 to the electroless plating electrode film 110 occurs, has the higher wire bonding strength. In addition, the inventors have found that it is preferable that the recessed depth of the bonding portion of the electroless plating electrode film 110 to the bonding wire 150 is set to be equal to or less than 1.5 μm in order to obtain such a shape of the bonding wire 150.

In addition, it is possible to diminish the strain which the capillary and the electroless plating electrode film 110 suffer at time of wire bonding, by lessening the recessed depth of the bonding portion of the electroless plating electrode film 110 to the bonding wire 150. For this reason, it is possible to not only lessen the abrasion of the capillary (improvement in mass production), but also reduce the possibility of damages to the electroless plating electrode film 110 and the interconnect inside the multilayered substrate of the lower layer thereof (micro-crack, T/C resistance), and the like. Hereby, improvement in the reliability of the semiconductor device 100 can be achieved.

Since hundreds of the bonding wires 150 exist in one semiconductor device 100 (package), it is difficult to observe the connection states of each of the bonding wires 150 at the time of manufacturing. For this reason, it is necessary to perform bonding having the high reliability. According to the configuration of the semiconductor device 100 in the embodiment, it is possible to perform good wire bonding onto the electroless plating electrode film 110, and to stably manufacture the semiconductor device 100 with the high reliability.

As described above, the embodiments of the invention has been set forth with reference to the drawings, they are only illustrative of the invention, and various configurations other than the foregoing can be adopted.

It is apparent that the present invention is not limited to the above embodiment, and may be modified and changed without departing from the scope and spirit of the invention.

What is claimed is:

1. A semiconductor device comprising:
a substrate over one surface of which an electroless plating electrode film is formed;
a semiconductor chip mounted over said one surface of said substrate; and
a bonding wire which connects said semiconductor chip and one surface of said electroless plating electrode film, a recessed depth which is a difference between a lowermost height of a bonding portion of said one surface of said electroless plating electrode film to said bonding wire, and an uppermost height of said one surface other than said bonding portion being equal to or less than 1.5 μm.

2. The semiconductor device as set forth in claim 1, wherein a minimum thickness of a bonding portion of said bonding wire to said electroless plating electrode film is equal to or more than 2.0 μm.

3. The semiconductor device as set forth in claim 1, wherein said electroless plating electrode film includes an electroless plating metal layer, and an electroless plating Au layer formed over said electroless plating metal layer, and
wherein Vickers hardness (HV) of said electroless plating metal layer is equal to or more than 400.

4. The semiconductor device as set forth in claim 3, wherein said electroless plating metal layer includes Ni.

5. The semiconductor device as set forth in claim 3, wherein said electroless plating metal layer includes an electroless plating Ni layer, and an electroless plating Pd layer formed between said electroless plating Ni layer and said electroless plating Au layer.

6. The semiconductor device as set forth in claim 5, wherein a thickness of said electroless plating Ni layer of said electroless plating metal layer is in the range of equal to or more than 1.0 μm and equal to or less than 15.0 μm.

7. The semiconductor device as set forth in claim 3, wherein a film thickness of said electroless plating Au layer is in the range of equal to or more than 0.01 μm and equal to or less than 0.7 μm.

8. The semiconductor device as set forth in claim 1, wherein said electroless plating electrode film includes phosphorus (P).

9. The semiconductor device as set forth in claim 1, wherein said electroless plating electrode film is amorphous.

10. A method of manufacturing a semiconductor device, comprising,
connecting a semiconductor chip and one surface of an electroless plating electrode film through a bonding wire, said electroless plating electrode film being formed over one surface of a substrate, said semiconductor chip being mounted over said one surface of said substrate, and said connecting the semiconductor chip and the one surface of the electroless plating electrode film through the bonding wire, including leading out a portion of said bonding wire from a tip of a capillary, bringing said capillary into contact with said one surface of said electroless plating electrode film, and connecting said portion of said bonding wire to said one surface of said electroless plating electrode film so that a recessed depth which is a difference between a lowermost height of a bonding portion of said one surface of said electroless plating electrode film to said bonding wire, and an uppermost height of said one surface other than said bonding portion becomes equal to or less than 1.5 μm.

11. The method of manufacturing the semiconductor device as set forth in claim 10, wherein in said step of connecting said portion of said bonding wire to said electroless plating electrode film, said portion of said bonding wire is connected to said electroless plating electrode film so that a minimum thickness of a bonding portion of said bonding wire to said electroless plating electrode film becomes equal to or more than 2.0 μm.

12. The method of manufacturing the semiconductor device as set forth in claim 10, wherein the step of connecting the semiconductor chip and the one surface of the electroless plating electrode film through the bonding wire further includes leading out one end of said bonding wire from the tip of said capillary and connecting said one end to said semiconductor chip, before the step of connecting said portion of said bonding wire to said electroless plating electrode film, and
wherein another part of said bonding wire one end of which is connected to said semiconductor chip is connected to said one surface of said electroless plating electrode film semiconductor chip as said portion.
